(19) United States
(12) Patent Application Publication
(10) Pub. No.: US 2017/0186994 A1
(43) Pub. Date: Jun. 29, 2017

(54) ORGANIC LIGHT-EMITTING DISPLAY PANEL, DISPLAY APPARATUS CONTAINING THE SAME, AND RELATED PACKAGING METHOD

(71) Applicant: BOE TECHNOLOGY GROUP CO., LTD, Beijing (CN)

(72) Inventor: ZHENGYIN XU, Beijing (CN)

(21) Appl. No.: 15/122,681

(22) PCT Filed: Dec. 10, 2015
(86) PCT No.: PCT/CN2015/096905

§ 371 Date: Aug. 31, 2016

(30) Foreign Application Priority Data
Aug. 11, 2015 (CN) 201510490974.7

(51) Int. Cl. H01L 51/52; H01L 51/56

(52) U.S. Cl. CPC H01L 51/5246; H01L 51/56; H01L 51/5243; H01L 2251/301; H01L 2251/558

(57) ABSTRACT

The present disclosure provides a method for packaging an organic light-emitting diode (OLED) display panel. The method includes providing a first substrate and a second substrate; forming a first bonding layer in a packaging region of the first substrate; and forming a second bonding layer in a packaging region of the second substrate. The method also includes bonding the first substrate with the second substrate by molecular bonding between the first bonding layer and the second bonding layer.

### CROSS-REFERENCES TO RELATED APPLICATIONS

This PCT patent application claims priority of Chinese Patent Application No. 201510490974.7, filed on Aug. 11, 2015, the entire content of which is incorporated by reference herein.

### FIELD OF THE INVENTION

The present invention generally relates to the display technologies and, more particularly, relates to an organic light-emitting (OLED) display panel and display apparatus containing the same, and related packaging method.

### BACKGROUND

Organic light-emitting (OLED) display technology is a promising display technology for flat-screen displays. The OLED display panels have advantages such as high color contrast, wide viewing angles, thin in volume, and no backlight. Accordingly, the technology to package OLED display panels has been a focus of research.

Currently, commonly used packaging technology for OLED display panels often include using ultraviolet (UV) glues, UV glues combined with desiccant, frit, etc. The packaging technology using UV glues often has poor sealing performance and is often not able to ensure desired service time of the packaged OLED display panel. The packaging technology using UV glues combined with desiccant is often not able to meet the production requirements for top-emitting OLED display panels. The packaging technology using frit often generates high strains in the packaged OLED display panel and the packaged OLED display panel is susceptible to cracking, which makes the packaging technology not suitable for packaging large-sized display devices.

### BRIEF SUMMARY OF THE DISCLOSURE

The present disclosure provides a light-emitting display panel, a display apparatus containing the display panel, and the related packaging method. By using the display panel and the related packaging method, better encapsulation performance may be obtained and no expensive packaging materials are required. The packaging process can be less costly and narrow bezel designs may be easier to implement.

One aspect of the present disclosure includes a method for packaging an organic light-emitting diode (OLED) display panel. The method includes providing a first substrate and a second substrate; forming a first bonding layer in a packaging region of the first substrate; and forming a second bonding layer in a packaging region of the second substrate. The method also includes bonding the first substrate with the second substrate by molecular bonding between the first bonding layer and the second bonding layer.

Optionally, the method further includes forming the first bonding layer in the packaging region on a top surface of the first substrate, the top surface facing the second substrate; and forming the second bonding layer in the package region on the second substrate to correspond to the first bonding layer.

Optionally, the method further includes forming a first silicon film in the packaging region on the top surface of the first substrate; performing a surface activation treatment on the first silicon film to form the first bonding layer; forming a second silicon film in the packaging region of the second substrate; and performing the surface activation treatment on the second silicon film to form the second bonding layer.

Optionally, the method further includes: forming a packaging strip in the packaging region of the first substrate, the packaging strip being between the first substrate and the first bonding layer.

Optionally, the packaging strip is an integral part of the first substrate.

Optionally, a process for forming the first silicon film includes vapor deposition, ion beam deposition, or a combination thereof, a thickness of the first silicon film being about 5 to 50 nm; and a process for forming the second silicon film includes vapor deposition, ion beam deposition, or a combination thereof, a thickness of the second silicon film being about 5 to 50 nm.

Optionally, the method further includes: using ion beams containing metal ions in the surface activation treatment of the first silicon film to form the first bonding layer with metal-silicon alloy regions, a thickness of the first bonding layer being about 1 to about 3 nm; and using ion beams containing metal ions for the surface activation treatment of the second silicon film to form the second bonding layer with metal-silicon alloy regions, a thickness of the second bonding layer being about 1 to about 3 nm.

Optionally, the metal ions include iron ions, copper ions, chromium ions, or a combination thereof.

Optionally, the method further includes: bonding the first substrate and the second substrate under a room temperature, over about 30 to 120 seconds, with a bonding pressing force of about 1 to 10 MPa.

Optionally, the room temperature is about 15 to about 35 degrees Celsius.

Optionally, the method further includes: polishing the top surface of the packaging strip before forming the first bonding layer on the packaging strip.

Optionally, the first bonding layer and the second bonding layer are formed in a vacuum environment; and the first substrate and the second substrate are bonded in a vacuum environment.

Optionally, a thickness of the packaging strip is about 2 to about 20 μm; and a width of the packaging strip is about 0.3 to about 1 mm.

Another aspect of the present disclosure provides an organic light-emitting diode (OLED) display panel. The OLED display panel includes a first substrate; a second substrate; a bonding layer sandwiched between the first substrate and the second substrate, the bonding layer comprising a first bonding layer, a second bonding layer, and metal-silicon alloy regions doped in the first bonding layer and the second bonding layer; and a plurality of OLEDs contained in an enclosure between bonded first substrate and second substrate. The first bonding layer is formed in a packaging region of the first substrate and the second bonding layer is formed in a packaging region of the second substrate.

Optionally, a packaging strip is in the packaging region of the first substrate between the first substrate and the first bonding layer, the first bonding layer being on a top surface of the packaging strip, the top surface of the packaging strip facing the second substrate; and the second bonding layer is in the packaging region of the second substrate to correspond to the packaging strip.

Optionally, the packaging strip is an integral part of the first substrate.

Optionally, the metal-silicon alloy regions in the first bonding layer has a thickness of about 1 to about 3 nm; the metal-silicon alloy regions in the second bonding layer has a thickness of about 1 to about 3 nm; and a composition of metal in the metal-silicon alloy regions in the first bonding layer is same as a composition of metal in the metal-silicon alloy regions in the second bonding layer.

Optionally, metal in the metal-silicon regions includes iron, copper, chromium, or a combination thereof.

Optionally, a thickness of the packaging strip is about 2 to about 20 μm; and a width of the packaging strip is about 0.3 to about 1 mm.

Another aspect of the present disclosure provides a display apparatus. The display apparatus includes one or more of the disclosed display panel.

Other aspects of the present disclosure can be understood by those skilled in the art in light of the description, the claims, and the drawings of the present disclosure.

### BRIEF DESCRIPTION OF THE DRAWINGS

The following drawings are merely examples for illustrative purposes according to various disclosed embodiments and are not intended to limit the scope of the present disclosure.

FIG. 1 illustrates a process flow of an exemplary packaging method according to the embodiments of the present disclosure;

FIG. 2 illustrates a process flow of step S1 in the packaging method according to the embodiments of the present disclosure;

FIG. 3 illustrates a process flow of step S12 in the packaging method according to the embodiments of the present disclosure; and

FIGS. 4(a)-4(d) illustrate cross-sectional views of an OLED display panel in various stages of an exemplary packaging process according to the embodiments of the present disclosure.

### DETAILED DESCRIPTION

For those skilled in the art to better understand the technical solution of the invention, reference will now be made in detail to exemplary embodiments of the invention, which are illustrated in the accompanying drawings. Wherever possible, the same reference numbers will be used throughout the drawings to refer to the same or like parts.

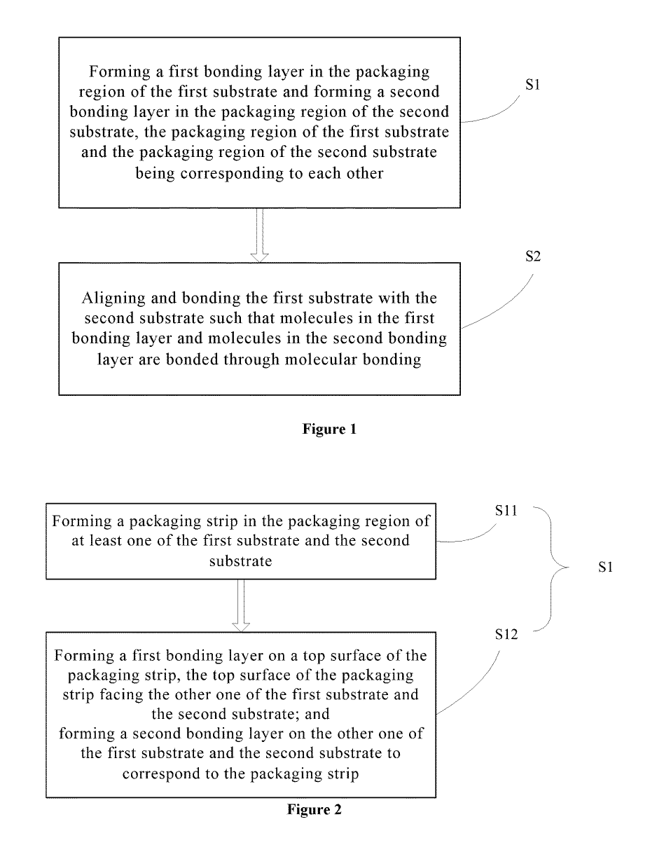

One aspect of the present disclosure provides a packaging method for the OLED display panel. The OLED display panel may include two substrates, e.g., a first substrate and a second substrate. The two substrates are to be packaged. As shown in FIG. 1, the packaging method may include steps S1 and S2.

In step S1, a first bonding layer may be formed in a packaging region of the first substrate and a second bonding layer may be formed in a packaging region of the second substrate. The packaging region of the first substrate may correspond to the packaging region of the second substrate. The correspondence between the packaging region of the first substrate and the packaging region of the second substrate may refer to the location of the packaging region of the first substrate being corresponding to the packaging region of the second substrate when the two substrates are aligned and/or bonded with each other.

In step S2, the first substrate may be aligned and bonded with the second substrate such that the first bonding layer is bonded with the second bonding layer. The bonding of the first bonding layer and the second bonding layer may include the molecules in the first bonding layer bonding with the molecules in the second bonding layer. The OLED display panel may be packaged.

Often, a packaging region may refer to a region beyond the display area, e.g., the region surrounding the display area. The first bonding layer may refer to a structure used in the bonding process for the packaging of the OLED display panel. The first bonding layer may be formed after a surface activation treatment in the packaging region of the first substrate. The second bonding layer may also refer to a structure used in the bonding process for the packaging of the OLED display panel. The second bonding layer may be formed after a surface activation treatment in the packaging region of the second substrate. After the first substrate is aligned with the second substrate, the first bonding layer should at least partially overlap with the second bonding layer such that the first substrate and the second substrate may be packaged together through the bonding process.

The bonding force in the packaging process of the present disclosure may be the Van der Waals forces among molecules. The first substrate and the second substrate may be bonded together tightly. The bonding formed between the first substrate and the second substrate may have stable chemical properties and may not be susceptible to cracking and/or failure.

In the present disclosure, molecular bonding technology is used to package the two substrates of the OLED display panel. Compared to the packaging technology using UV glues, the method provided by the present disclosure has improved sealing performance. Compared to the packaging technology using frit, the method provided by the present disclosure does not require expensive frit materials and avoids the cracking problems caused by high strain in the frit. Also, the disclosed method takes less time than the packaging methods involving coating UV glues and/or printing and soldering frit. Fabrication or production efficiency can thus be improved.

Further, the packaging process provided by the present disclosure causes little or no damages to the light-emitting materials of the OLED display panel. The packaging regions of the OLED display panel may be sufficiently close to the light-emitting material. Narrow bezel designs can be better implemented.

In some embodiments, step S1 may also include forming a packaging strip in the packaging region of at least one of the first substrate and the second substrate. The step S1 may further include forming the first bonding layer on the packaging strip on the first substrate and/or forming the second bonding layer on the packaging strip on the second substrate. It should be noted that, the packaging strip is optional. That is, the OLED display panel may only require the first bonding layer and the second bonding layer, to be bonded together. The packaging strip may also be formed after the first substrate is provided, or may be provided together with the first substrate. For example, the first substrate may be sufficiently thick so that no packaging strip is required. The specific formation of the packaging strip may not be limited by the embodiments of the present disclosure. In one embodiment, the packaging strip may be formed after the first substrate is provided.

In the OLED display panel, a space may be formed between the two substrates aligned with each other. The space may be used to contain the OLED, the thin-film transistors (TFTs), and other related components. Often, the thickness of the first bonding layer and the thickness of the second bonding layer may each be several nanometers, and the thickness of the packaging strip may be several micrometers. In the present disclosure, by applying a packaging strip on the first substrate and/or the second substrate, forming the first bonding layer and the second bonding layer each on the corresponding packaging strip, and adjusting the thickness of the packaging strip, the distance between the first substrate and the second substrate may be adjusted. The two substrates, aligned and bonded with each other, may have sufficient space in between to contain the OLED, the TFTs, and other related components. In certain embodiments, no TFTs are contained in the enclosed space.

In some embodiments, the packaging strip formed on the first substrate and the first substrate may be formed as one piece. The packaging strip formed on the second substrate and the second substrate may be formed as one piece. That is, a packaging strip and the corresponding substrate, i.e., the first substrate or the second substrate, may be formed as a one-piece structure. In this case, fewer fabrication steps may be required.

Further, as shown in FIG. 2, step S1 may include steps S11 and S12.

In step S11, a packaging strip may be formed in the packaging region of at least one of the first substrate and the second substrate.

In step S12, the first bonding layer may be formed on a top surface of the packaging strip. The top surface of the packaging strip facing the other one of the first substrate and the second substrate. The second bonding layer may be formed on the region on the other one of the first substrate and the second substrate to correspond to the packaging strip.

The region corresponding to the packaging strip may refer to the region corresponding to the location of the packaging strip. In some embodiments, the thickness of the packaging strip may be about 2 to 20 μm. The width of the packaging strip may be about 0.3 to 1 mm.

Also, to enhance the sealing performance of the subsequently packaged display panel, the packaging strip may be a loop-shaped sealant strip surrounded by the outer periphery of the first substrate or by the outer periphery of the second substrate. If the packaging strip is formed on the first substrate, the packaging strip may be a loop-shaped sealant strip surrounded by the outer periphery of the first substrate. If the packaging strip is formed on the second substrate, the packaging strip may be a loop-shaped sealant strip surrounded by the outer periphery of the second substrate. It should be noted that, the packaging strip being surrounded by the outer periphery of the corresponding substrate is merely used to describe that the packaging strip is formed on the substrate and does not extend beyond the edges of the substrate. The shape of the packaging strip may or may not follow the shape of the outer periphery of the corresponding substrate.

The packaging strip may be made of any suitable materials. The material for forming the packaging strip may be able to undergo physical and/or chemical etching processes to form a structure with a predetermined pattern. It should be noted that, to ensure the sealing performance of the subsequently packaged OLED display panel, the packaging strip should be sufficiently flat, and the thickness of the packaging strip may be sufficiently uniformed. Alternatively, the first substrate and the corresponding packaging strip may be formed as one piece, and/or the second substrate and the corresponding packaging strip may be formed as one piece.

Further, as shown in FIG. 3, step S12 may include steps S121 to S124.

In step S121, a first silicon film may be formed on the top surface of the packaging strip on one of the first substrate and the second substrate. The top surface of the packaging strip facing the other one of the first substrate and the second substrate.

In step S122, the surface activation treatment may be performed on the first silicon film to form the first bonding layer.

In step S123, a second silicon film may be formed on the region on the other one of the first substrate and the second substrate, the region being corresponding to the packaging strip.

In step S124, the surface activation treatment may be performed on the second silicon film to form the second bonding layer.

The processes to form the first silicon film and the second silicon film may be any suitable deposition methods. For example, in step S121, vapor deposition and/or ion beam deposition methods may be used to form the first silicon film on the top surface of the packaging strip on one of the first substrate and the second substrate. In some embodiments, the thickness of the first silicon film may be about 5 to 50 nm. Accordingly, in step S123, vapor deposition and/or ion beam deposition methods may be used to form the second silicon film on the region corresponding to the packaging strip, on the other one of the first substrate and the second substrate. In some embodiments, the thickness of the second silicon film may be about 5 to 50 nm.

As an embodiment of the present disclosure, metal ions may be used in an ion beam cleaning process to clean the silicon films for the surface activation treatment.

For example, in step S122, ion beams containing metal ions may be used in the surface activation treatment of the first silicon film to form the first bonding layer with metal-silicon alloy regions. The thickness of the first bonding layer may be about 1 to 3 nm. Accordingly, in step S124, same surface activation treatment as in step S122 may be performed on the second silicon film to form the second bonding layer. The second bonding layer may include metal-silicon alloy regions. The thickness of the second bonding layer may be about 1 to 3 nm.

In the present disclosure, the metal of the metal ions may include iron, copper, chromium, and/or other suitable metal ions that can form alloys with silicon. That is, in step S122, ion beams containing iron ions, copper ions, and/or chromium ions may be used in the surface activation treatment of the first silicon film to form the first bonding layer with iron-silicon alloy regions, copper-silicon alloy regions, and/or chromium-silicon alloy regions. Accordingly, in step S124, same ion beams as in step S122 may be performed on the second silicon film to form the second bonding layer. The second bonding layer may include iron-silicon alloy regions, copper-silicon alloy regions, or chromium-silicon alloy regions.

It should be noted that, the metal contained or doped into the first bonding layer and the second bonding layer may be the same. That is, the first bonding layer and the second bonding layer may both include iron-silicon alloy regions. The first bonding layer and the second bonding layer may both include copper-silicon alloy regions. Also, the first bonding layer and the second bonding layer may both include chromium-silicon alloy regions. Thus, the molecules in the first bonding layer and the molecules in the second bonding layer may form desired molecular bonds in the packaging process.

Often, the bonding strength or strength of the bonds formed in the bonding process of iron-silicon regions may be desirably high. The subsequently packaged OLED display panel may have desired sealing performance and structural stability.

In one embodiment, the bonding process described in step S2 may be performed under room temperature. In some embodiments, the bonding process may be performed between about 15 to 35 degrees Celsius. The bonding time may be about 30 to 120 seconds. The bonding pressing force may be about 1 to about 10 Mpa. The bonding pressing force may refer to the force required to bond the two substrates together.

Because the packaging method provided by the present disclosure may be performed under room temperature, high temperature operation may be avoided and cracking issues due to overly high strain in the packaging materials can be avoided. Also, operation under room temperature may cause little or no damages to the light-emitting materials and can be performed sufficiently close to the periphery of the light-emitting material. Narrow bezel design of the OLED display panel can be better implemented.

To ensure the packaging strips have desired flatness and further improve the packaging process, in some embodiments, after step S11, the packaging method may further include polishing the top surface of the packaging strip, where the packaging strip may be formed on one of the first substrate and the second substrate. The top surface of the packaging strip may face the other one of the first substrate and the second substrate.

To better clean the top surface of the packaging strip, in some embodiments, the packaging method may further include a plasma cleaning process after polishing the top surface of the packaging strip.

Further, the packaging process described in steps S1 and S2 may both be performed in vacuum to avoid adverse effect of particles and/or other unpurified matters.

Often, the first substrate may be the packaging cover and the second substrate may be the display substrate. The second substrate may include a substrate or base substrate. TFTs, OLEDs, and other related components may be formed on the base substrate.

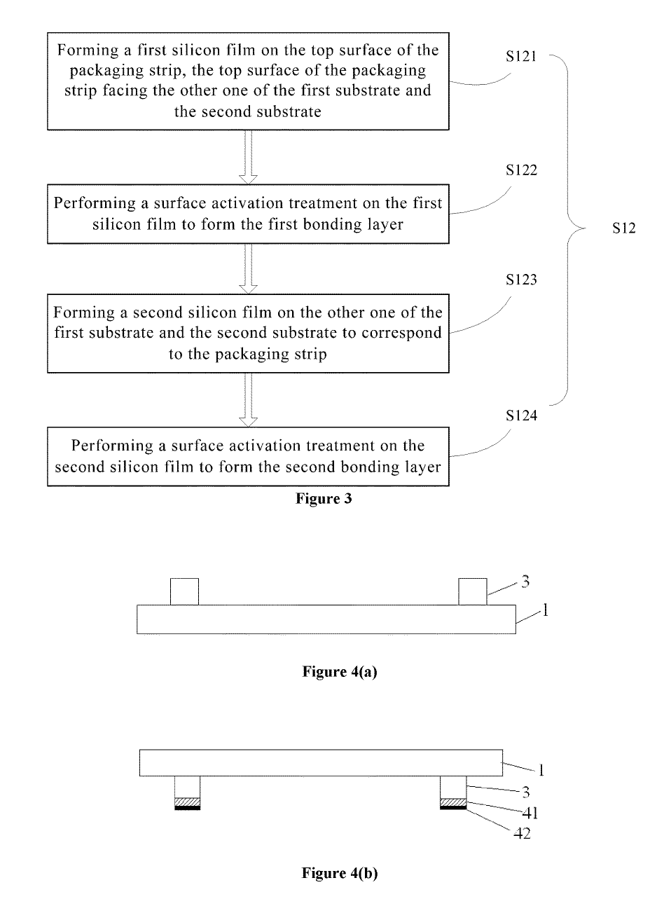

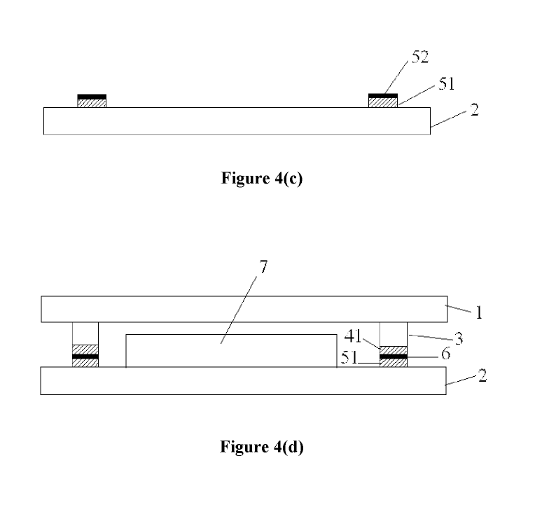

The packaging method provided by the present disclosure is further illustrated in detail in relation to FIGS. 4(a) to 4(d).

At the beginning of the process, a packaging strip 3 with a predetermined pattern may be formed on the first substrate 1. The packaging strip 3 may be mechanically polished, as shown in FIG. 4(a). The pattern may be formed by a physical and/or chemical etching process. The height of the packaging strip 3 may be about 2 to 20 μm. The width of the packaging strip 3 may be about 0.3 to 1 mm. The packaging strip 3 may have a uniformed thickness so that the top surface of the packaging strip 3 facing the second substrate 2 may be flat.

Further, TFTs may be formed on the second substrate 2. OLEDs may be formed on the second substrate 2 in vacuum. Other related components may also be formed on the second substrate 2.

Further, a plasma cleaning process may be performed on the first substrate 1 with the packaging strip 3. Further, a first silicon film 41 may be formed on the packaging strip 3. The first silicon film 41 may be formed by an ion beam deposition and/or vapor deposition method. The first silicon film 41 may be about 5 to 50 nm thick. Further, a surface activation treatment may be performed on the first silicon film 41 to increase the surface activation energy. Ion beams containing iron ions may be used in the surface activation treatment. A first bonding layer 42, as shown in FIG. 4(b), may be formed. The first bonding layer 42 may include iron-silicon alloy regions. The thickness of the first bonding layer 42 may be about 1 to 3 nm.

In the process described above, one or more masks may be used to control the positions and the precision of the depositions.

Further, the second silicon film 51 may be formed on the second substrate 2. The location of the second silicon film 51 may correspond to the location of the packaging strip 3. The second silicon film 51 may be formed by ion beam deposition and/or vapor deposition. The second silicon film 51 may be about 5 to 50 nm thick. Further, a surface activation treatment may be performed on the second silicon film 51 to increase the surface activation energy. Ion beams containing iron ions may be used in the surface activation treatment. A second bonding layer 52, as shown in FIG. 4(c), may be formed. The second bonding layer 52 may include iron-silicon alloy regions. The thickness of the second bonding layer 52 may be about 1 to 3 nm.

Further, the first substrate 1 and the second substrate 2 may be aligned with each other so that corresponding parts or locations can be aligned properly. The first bonding layer 42 and the second bonding layer 52 may be bonded in vacuum. The bonding process may be performed under about 15 to 35 degrees Celsius. The bonding time may be about 30 to 120 seconds. The bonding pressing force may be about 1 to 10 MPa. A connection structure or connection portion 6, as shown in FIG. 4(d), may be formed. The packaging process may be completed.

In the process described above, the first substrate 1 may be the packaging cover and the second substrate 2 may be the display substrate. The packaging strip 3 may be formed on the first substrate 1. The second substrate 2 may include a substrate or base substrate, and TFTs (not shown), OLEDs 7, and other related components formed on the base substrate. For illustrative purposes, only one OLED 7 is shown. In practice, a plurality of OLEDs may be formed on the base substrate.

Another aspect of the present disclosure provides an OLED display panel. The OLED display panel may include a first substrate and a second substrate. The packaging region of the first substrate may include a first bonding layer. The packaging region of the second substrate may include a second bonding layer. The packaging region of the first substrate and the packaging region of the second substrate may correspond to each other. Molecules in the first bonding layer and molecules in the second bonding layer may be bonded to form a connection portion.

The bonding process may refer to the molecular bonding technology. That is, a surface activation treatment may be performed on the to-be-packaged regions on the first substrate and the second substrate to form the first bonding layer and the second bonding layer. The first bonding layer and the second bonding layer may facilitate the molecular bonding process. The first bonding layer may at least partially overlap with the second bonding layer so that the first substrate and the second substrate may be packaged through the bonding process.

In the present disclosure, the two substrates of the OLED display panel may be bonded by the molecular bonding technology. Compared to packaging technology using UV glues, the disclosed packaging process may have better sealing performance. Compared to packaging technology using frit, the disclosed packaging process does not require expensive frit materials and may avoid cracking caused by high strain. Also, the disclosed packaging process may take less time compared to the process involving coating with UV glues and/or printing and soldering frit. Fabrication or production efficiency can thus be improved.

In addition, little or no damages to the light-emitting materials may be caused during the disclosed packaging process. The bonding process may be performed sufficiently close to the periphery of the light-emitting material. Narrow bezel designs may be better implemented.

Further, a packaging strip may be formed in the packaging region of at least one of the first substrate and the second substrate. The first bonding layer may be formed in the packaging region of the first substrate, and/or the second bonding layer may be formed in the packaging region of the second substrate.

In the OLED display panel, certain space may be kept between the bonded two substrates. The space may be used to place OLEDs, TFTs, and other related components. Thus, the thickness of the packaging strip may be adjusted to control or adjust the distance between the first substrate and the second substrate. Sufficient space between the bonded two substrates may be formed or kept to accommodate OLEDs, TFTs, and other related components.

In some embodiments, the thickness of the packaging strip may be about 2 to 20 μm, and the width of the packaging strip may be about 0.3 to 1 mm. The packaging strip may be a loop-shaped packaging strip surrounded or enclosed by the outer periphery of the first substrate and/or the second substrate.

In the embodiments of the present disclosure, the packaging strip formed on the first substrate may form one piece with the first substrate. The packaging strip formed on the second substrate may form one piece with the second substrate to improve mechanical strength. Fewer fabrication steps may be required.

In some embodiments, a packaging strip may be formed on one of the first substrate and the second substrate. The first bonding layer may be formed on the top surface of the packaging strip. The top surface of the packaging strip may face the other one of the first substrate and the second substrate. The second substrate may be formed on a region on the other one of the first substrate and the second substrate. The location of the region may correspond to the location of the packaging strip.

For example, in FIGS. 4(a) to 4(d), the packaging strip 3 may be formed on the first substrate 1. The first bonding layer 42 may be formed on the top surface of the packaging strip 3. The top surface of the packaging strip 3 faces the second substrate 2. The second bonding layer 52 may be formed on a region on the second substrate 2. The location of the region may correspond to the location of the packaging strip 3. The packaging strip 3 and the second substrate 2 may be bonded or packaged together through the molecular bonding between the molecules in the first bonding layer 42 and the molecules in the second bonding layer 52.

Specifically, the first silicon film 41 may be formed on the top surface of the packaging strip 3, where the top surface of the packaging strip 3 faces the second substrate 2. The first bonding layer 42 may be formed on the first silicon film 41. The second silicon film 51 may be formed on the region corresponding to the packaging strip 3 on the second substrate 2. The second bonding layer 52 may be formed on the second silicon film 51.

In some embodiments, the first silicon film 41 may be formed on the packaging strip 3. The thickness of the first silicon film 41 may be about 5 to 50 nm. Accordingly, the second silicon film 51 may be formed on the region corresponding to the packaging strip 3 on the second substrate 2. The thickness of the second silicon film 51 may be about 5 to 50 nm.

In some embodiments, the first bonding layer 42 may include metal-silicon alloy regions. The thickness of the first bonding layer 42 may be about 1 to 3 nm. Accordingly, the second bonding layer 52 may include metal-silicon alloy regions. The thickness of the second bonding layer 52 may be about 1 to 3 nm. Also, the metal contained in the metal-silicon alloy regions of the first bonding layer 42 may be the same as the metal contained in the metal-silicon alloy regions of the second bonding layer 52.

The metal may be iron, copper, chromium, and/or any suitable material that can form alloys with silicon.

The first substrate 1 may be the packaging cover and the second substrate 2 may be the display substrate. The packaging strip 3 may be formed on the first substrate 1. The second substrate 2 may include a substrate or base substrate, TFTs (not shown), OLEDs 7, and other related components formed on the second substrate 2. For illustrative purposes, only one OLED 7 is shown. In practice, a plurality of OLEDs may be formed on the second substrate 2. It should be noted that, the packaging strip 3 may also be formed on the second substrate 2, or formed on both the first substrate 1 and the second substrate 2.

Another aspect of the present disclosure provides a display apparatus. The display apparatus may incorporate one or more of the above-mentioned OLED display panels. The OLED display panel incorporated in the display apparatus may be packaged using surface activation molecular bonding technologies. The packaging of the OLED display panel may have improved sealing performance and structural stability. Also, because the packaging process of the OLED display panel does not require high-temperature and the related cooling process, cracking issues caused by high strain may be avoided. Damages to the light-emitting materials may be avoided. The packaging process may be performed sufficiently close to the periphery of the light-emitting materials. Narrow bezel designs may be easier to implement. The display apparatus according to the embodiments of the present disclosure can be used in any product with display functions such as a television, an electronic paper, a digital photo frame, a mobile phone, and a tablet computer.

It should be understood that the above embodiments disclosed herein are exemplary only and not limiting the scope of this disclosure. Without departing from the spirit and scope of this invention, other modifications, equivalents, or improvements to the disclosed embodiments are obvious to those skilled in the art and are intended to be within the scope of the present disclosure.

1-20. (canceled)

21. A method for packaging an organic light-emitting diode (OLED) display panel, comprising:
providing a first substrate and a second substrate;
forming a first bonding layer in a packaging region of the first substrate;
forming a second bonding layer in a packaging region of the second substrate; and
bonding the first substrate with the second substrate by molecular bonding between the first bonding layer and the second bonding layer.

22. The method according to claim 21, further including:
forming the first bonding layer in the packaging region on a top surface of the first substrate, the top surface facing the second substrate; and
forming the second bonding layer in the package region on the second substrate to correspond to the first bonding layer.

23. The method according to claim 22, further including:
forming a first silicon film in the packaging region on the top surface of the first substrate;
performing a surface activation treatment on the first silicon film to form the first bonding layer;
forming a second silicon film in the packaging region of the second substrate; and
performing the surface activation treatment on the second silicon film to form the second bonding layer.

24. The method according to claim 21, further including: forming a packaging strip in the packaging region of the first substrate, the packaging strip being between the first substrate and the first bonding layer.

25. The method according to claim 24, wherein the packaging strip is an integral part of the first substrate.

26. The method according to claim 23, wherein:
a process for forming the first silicon film includes vapor deposition, ion beam deposition, or a combination thereof, a thickness of the first silicon film being about 5 to 50 nm; and
a process for forming the second silicon film includes vapor deposition, ion beam deposition, or a combination thereof, a thickness of the second silicon film being about 5 to 50 nm.

27. The method according to claim 23, further including:
using ion beams containing metal ions in the surface activation treatment of the first silicon film to form the first bonding layer with metal-silicon alloy regions, a thickness of the first bonding layer being about 1 to about 3 nm; and
using ion beams containing metal ions for the surface activation treatment of the second silicon film to form the second bonding layer with metal-silicon alloy regions, a thickness of the second bonding layer being about 1 to about 3 nm.

28. The method according to claim 27, wherein:
the metal ions include iron ions, copper ions, chromium ions, or a combination thereof.

29. The method according to claim 21, further including:
bonding the first substrate and the second substrate under a room temperature, over about 30 to 120 seconds, with a bonding pressing force of about 1 to 10 MPa.

30. The method according to claim 29, wherein the room temperature is about 15 to about 35 degrees Celsius.

31. The method according to claim 24, further including:
polishing the top surface of the packaging strip before forming the first bonding layer on the packaging strip.

32. The method according to claim 21, wherein:
the first bonding layer and the second bonding layer are formed in a vacuum environment; and
the first substrate and the second substrate are bonded in a vacuum environment.

33. The method according to claim 24, wherein a thickness of the packaging strip is about 2 to about 20 μm; and a width of the packaging strip is about 0.3 to about 1 mm.

34. An organic light-emitting diode (OLED) display panel, comprising:
a first substrate;
a second substrate;
a bonding layer sandwiched between the first substrate and the second substrate, the bonding layer comprising a first bonding layer, a second bonding layer, and metal-silicon alloy regions doped in the first bonding layer and the second bonding layer; and
a plurality of OLEDs contained in an enclosure between bonded first substrate and second substrate, wherein:
the first bonding layer is formed in a packaging region of the first substrate and the second bonding layer is formed in a packaging region of the second substrate.

35. The OLED display panel according to claim 34, wherein:
a packaging strip is in the packaging region of the first substrate between the first substrate and the first bonding layer, the first bonding layer being on a top surface of the packaging strip, the top surface of the packaging strip facing the second substrate; and the second bonding layer is in the packaging region of the second substrate to correspond to the packaging strip.

36. The OLED display panel according to claim 34, wherein the packaging strip is an integral part of the first substrate.

37. The OLED display panel according to claim 34, wherein:
the metal-silicon alloy regions in the first bonding layer has a thickness of about 1 to about 3 nm;
the metal-silicon alloy regions in the second bonding layer has a thickness of about 1 to about 3 nm; and
a composition of metal in the metal-silicon alloy regions in the first bonding layer is same as a composition of metal in the metal-silicon alloy regions in the second bonding layer.

38. The OLED display panel according to claim 37, wherein:
metal in the metal-silicon regions includes iron, copper, chromium, or a combination thereof.

39. The OLED display panel according to claim 36, wherein a thickness of the packaging strip is about 2 to about 20 μm; and a width of the packaging strip is about 0.3 to about 1 mm.

40. A display apparatus, including the display panel according to claim 34.
